(19) United States
(12) Patent Application Publication
(10) Pub. No.: US 2009/0155981 A1
(43) Pub. Date: Jun. 18, 2009

(54) METHOD AND APPARATUS FOR SINGULATING INTEGRATED CIRCUIT CHIPS

(76) Inventors: Stephen P. Ayotte, Bristol, VT (US); Timothy S. Hayes, Colchester, VT (US)

Correspondence Address: SCHMEISER, OLSEN & WATTS, 22 CENTURY HILL DRIVE, SUITE 302, LATHAM, NY, 12110, US

(21) Appl. No.: 11/955,495

(22) Filed: Dec. 13, 2007

(51) Int. Cl. H01L 21/78

(52) U.S. Cl. 438/462; 257/E21.599

(57) ABSTRACT

A method of singulating integrated circuit chips. The method includes forming, from a bottom surface of a substrate, trenches part way through the substrate in the kerf regions surrounding integrated circuit regions previously formed in the substrate; placing a top surface of the substrate on a singulation fixture having compartments, the walls of the compartments fitting into the trenches in the substrate; and thinning the bottom surface of the substrate until the individual integrated circuit regions are singulated into individual integrated circuit chips.

### FIELD OF THE INVENTION

The present invention relates to the field of integrated circuit chip fabrication; more specifically, it relates to a method for singulating integrated circuit chips.

### BACKGROUND OF THE INVENTION

It is advantageous in many applications to thin completed integrated circuit chips. Existing methods required attaching the front side of a wafer containing an array of integrated circuit chips to an adhesive tape, grinding the back side to the proper thickness, dicing from the back side to singulated the individual integrated circuit chips and then removing the adhesive tape from the front side of the individual integrated circuit chips. This process can damage the front side of the integrated circuit chips reducing yield or leave contaminants that reduce the reliability of the integrated circuit chips. Accordingly, there exists a need in the art to overcome the deficiencies and limitations described hereinabove.

### SUMMARY OF THE INVENTION

A first aspect of the present invention is a method comprising: providing a substrate having an array of integrated circuit regions, each integrated circuit region of the array of integrated circuit regions separated by a first set of parallel kerf regions aligned in a first direction and a second set of parallel kerf regions aligned in a second direction, the substrate having a top surface and a bottom surface, the first and second directions perpendicular to each other and parallel to the top surface of the substrate, the first and second sets of parallel kerf regions intersecting to form a first grid pattern defining the array of integrated circuit regions; forming a first set of parallel trenches in the first set of parallel kerf regions and forming a second set of parallel trenches in the second set of parallel kerf regions, the first and second sets of parallel trenches extending perpendicularly from the top surface of the substrate a first distance into the substrate, the first distance less than a second distance between the top and bottom surfaces of the substrate, the second distance measured perpendicularly from the top surface of the substrate; providing a singulation fixture having an array of compartments, each integrated compartment of the array compartments separated by a first set of parallel walls aligned in a third direction and a second set of parallel walls aligned in a fourth direction, the singulation fixture having a top surface and a bottom surface, the third and fourth directions perpendicular to each other and parallel to the top surface of the singulation fixture, the first and second sets of parallel walls intersecting to form a second grid pattern defining the array of compartments, each compartment open at the top surface and closed at the bottom surface of the singulation fixture; aligning and placing the substrate on the singulation fixture, the top surface of the substrate facing the top surface of the singulation fixture, the first and second sets of parallel trenches contacting top edges of the first and second set of parallel walls, each integrated circuit region of the set of integrated circuit regions aligned within corresponding and respective compartments of the singulation fixture; and thinning the substrate from the bottom surface of the substrate until individual integrated circuit regions of the substrate are singulated into individual integrated circuit chips, each integrated circuit chip contained in a respective compartment of the singulation fixture.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIGS. 1A through 1D are cross-sections illustrating singulation of integrated circuit chips from a common substrate according to embodiments of the present invention;

FIG. 2 is a top view of an exemplary integrated circuit substrate before singulation;

FIG. 3 is a top view of a singulation fixture according to embodiments of the present invention;

FIGS. 4A through 4D are cross-section views of alternative geometries for kerf cuts according to embodiments of the present invention; and

FIGS. 5A through 5D are cross-section views of alternative geometries for the edges of chip compartments of the singulation fixture of FIGS. 1C, 1D and 2 according to embodiments of the present invention

### DETAILED DESCRIPTION OF THE INVENTION

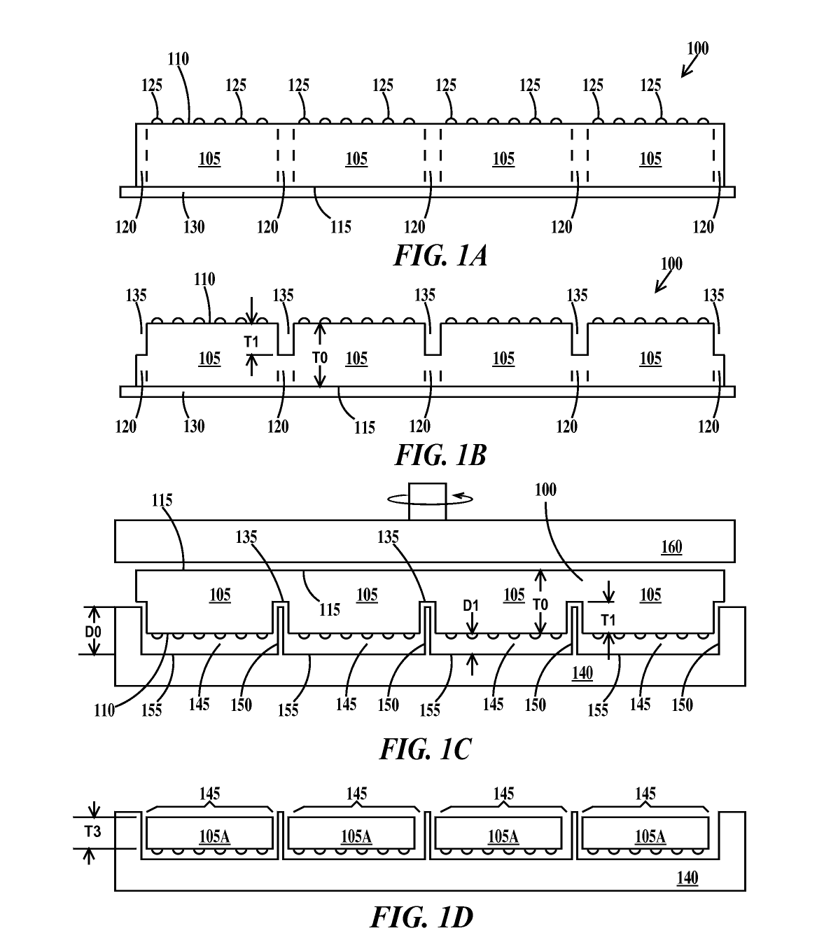

FIGS. 1A through 1D are cross-sections illustrating singulation of integrated circuit chips from a common substrate according to embodiments of the present invention. In FIG. 1A, a substrate 100 includes a plurality integrated circuits regions 105 formed in substrate 100 having a top surface 110 and a bottom surface 115. Integrated circuit regions 105 are separated from each other by kerf regions 120 of substrate 100. A plurality of solder bump connections 125 are formed on top surface 110 of substrate 100 in each of chip regions 105. Alternatively, solder bumps 125 may be replaced with bonding pads. Solder bumps are, in one example, semispherical elements comprising solder, lead solder or lead/tin solder formed on prepared pads and used in a process called controlled chip collapse connection (C4) to physically attach and electrically connect individual integrated circuits to modules. Bonding pads, in one example, are plates of metal used in a process called wire bonding to electrically connect individual integrated circuits to modules. In FIG. 1A, an optional self-adhesive dicing film 130 has been attached to bottom surface 115 of substrate 100.

In FIG. 1B, trenches 135 have been cut into kerf regions 120 between integrated circuit regions 135 from top surface 110. In a first example, trenches 135 are formed by sawing. Dicing saws may be single or multi-bladed. In a second example, trenches 135 are formed by laser oblation. Substrate 100 is held in position relative to the saw or laser by dicing film 130 if present. Alternatively, substrate 100 may be held in position relative to the saw or laser using a vacuum or electrostatic chuck. Substrate 100 has a thickness from top surface 110 to bottom surface 115 of T0. Trenches 135 have a depth measured from top surface 110 of substrate 100 into the substrate of T1, where T0 is greater than T1. T1 is just larger than a finished thickness T3 (see FIG. 1D) after the thinning process illustrated in FIG. 1C has been performed to allow for some over-thinning.

In FIG. 1C, substrate 105 is mounted top surface 110 facing a singulation fixture 140. Singulation fixture 140 includes a multiplicity of chip compartments 145 separated by walls 150. There is one compartment 145 for each integrated circuit region 105. Compartments 145 have a depth DO. Walls 150 are positioned to align within trenches 135 of substrate 100. When substrate 100 is placed on singulation fixtures 140, the top edges of walls 150 contact the bottoms of trenches 135 suspending top surface 110 of substrate 100 a distance D1 from the bottoms 155 of compartments 155. D1 plus the thickness of solder bump 125 (see FIG. 1B) is less than D0 and D0 is greater than T3 (see FIG. 1D) plus the thickness of solder bumps 125 (see FIG. 1B). After placing substrate in singulation fixture 140, bottom surface 115 of substrate is ground down using an abrasive grinding wheel 160. Alternatively a grinding belt may be used. Grinding may use a fixed abrasive attached to the wheel or belt or a slurry of abrasive injected between grinding wheel 160 (or belt) and substrate 100. The slurry may be chemically basic. Examples of suitable abrasives includes but are not limited to Al₂O₃, CeO and TaO.

In FIG. 1D, after grinding reaches trenches 135 (See FIG. 1C), singulated integrated circuit chips 105A are freed (no longer attached to each other by kerf regions of the substrate) and caught in compartments 145. The integrated circuit chips may be removed and cleaned. Note, no adhesive has touched top surface 100 of substrate 100 (see FIG. 1D) during the entire singulation process.

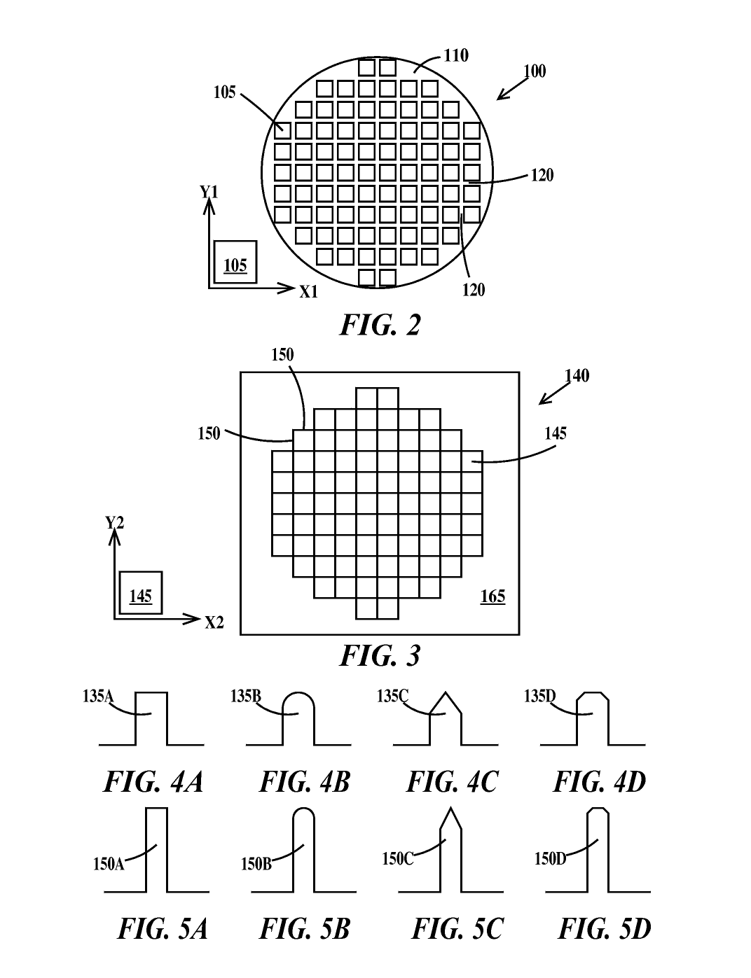

FIG. 2 is a top view of an exemplary integrated circuit substrate before singulation. In FIG. 2, substrate 100 includes an array of integrated circuit regions 105 separated by kerf regions 120. Note a first set of kerf regions 105 run in an X1-direction and a second set of kerf regions 105 run in a Y1 direction. The X1-and Y1 directions mutually perpendicular and parallel to a plane defined by top surface 110 of substrate 100.

FIG. 3 is a top view of a singulation fixture according to embodiments of the present invention. In FIG. 3, singulation fixture 140 includes an array of compartments 145 separated walls 150. Note, a first set of walls 150 run in the X2-direction and second set of walls 150 run in the Y2 direction. The X2 and Y2 directions are mutually perpendicular and parallel to a plane defined by a top surface 165 of singulation fixture 140. In one example, singulation fixture 140 comprises a plastic, a filled resin, an electrically conductive plastic or an electrically conductive filled resin.

Referring to FIGS. 2 and 3, After substrate 100 is placed on and aligned to singulation fixture 140, the X1 and X2 directions are the same direction and parallel to each other and the Y1 and Y2 directions are the same direction and parallel to each other.

FIGS. 4A through 4D are cross-section views of alternative geometries for kerf cuts according to embodiments of the present invention. In FIG. 4A, the bottom of notches 135A are flat. In FIG. 4B, the bottom of notches 135B are semicircular. In FIG. 4C, the bottom of the opposite sidewalls of notches 135C taper inward to a point. In FIG. 4A, the bottom of the opposite sidewalls of notches 135D taper inward with a flat in between.

FIGS. 5A through 5D are cross-section views of alternative geometries for the edges of chip compartments of the singulation fixture of FIGS. 1C, 1D and 2 according to embodiments of the present invention. In FIG. 5A, the top edge of walls 150A are flat. In FIG. 5B, the top edge of walls 150B are semicircular. In FIG. 5C, the opposite corners of the top edge of walls 150C are chamfered to meet in a point. In FIG. 5A, the opposite corners of the top edge of walls 150D are chamfered with a flat between.

Thus the embodiments of the present invention provide a method for singulating completed integrated circuit chips from a substrate that does not require contacting the front side of the integrated circuit chips with adhesive and that overcomes the aforementioned limitations in the prior art.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A method comprising:
providing a substrate having an array of integrated circuit regions, each integrated circuit region of said array of integrated circuit regions separated by a first set of parallel kerf regions aligned in a first direction and a second set of parallel kerf regions aligned in a second direction, said substrate having a top surface and a bottom surface, said first and second directions perpendicular to each other and parallel to said top surface of said substrate, said first and second sets of parallel kerf regions intersecting to form a first grid pattern defining said array of integrated circuit regions;
forming a first set of parallel trenches in said first set of parallel kerf regions and forming a second set of parallel trenches in said second set of parallel kerf regions, said first and second sets of parallel trenches extending perpendicularly from said top surface of said substrate a first distance into said substrate, said first distance less than a second distance between said top and bottom surfaces of said substrate, said second distance measured perpendicularly from said top surface of said substrate;
providing a singulation fixture having an array of compartments, each integrated compartment of said array compartments separated by a first set of parallel walls aligned in a third direction and a second set of parallel walls aligned in a fourth direction, said singulation fixture having a top surface and a bottom surface, said third and fourth directions perpendicular to each other and parallel to said top surface of said singulation fixture, said first and second sets of parallel walls intersecting to form a second grid pattern defining said array of compartments, each compartment open at said top surface and closed at said bottom surface of said singulation fixture;
aligning and placing said substrate on said singulation fixture, said top surface of said substrate facing said top surface of said singulation fixture, said first and second sets of parallel trenches contacting top edges of said first and second set of parallel walls, each integrated circuit region of said set of integrated circuit regions aligned within corresponding and respective compartments of said singulation fixture; and
thinning said substrate from said bottom surface of said substrate until individual integrated circuit regions of said substrate are singulated into individual integrated circuit chips, each integrated circuit chip contained in a respective compartment of said singulation fixture.

2. The method of claim 1, wherein said forming said first set of parallel trenches and forming said second set of parallel trenches includes sawing said substrate to form said first and second sets of parallel trenches.

3. The method of claim 1, wherein said forming said first set of parallel trenches and forming said second set of parallel trenches includes laser oblation of said substrate to form said first and second sets of parallel trenches.

4. The method of claim, wherein said thinning includes grinding with a fixed abrasive.

5. The method of claim, wherein said thinning includes grinding with an abrasive slurry.

6. The method of claim 1, wherein said top surface of said substrate in said integrated circuit regions includes an array of solder bumps.

7. The method of claim 1, further including:
prior to said forming said first set of parallel trenches and forming said second set of parallel trenches, attaching a self adhesive film to said bottom surface of said substrate; and
after said forming said first set of parallel trenches and forming said second set of parallel trenches, removing said self adhesive film from said bottom surface of said substrate.
